(19) United States
(12) Patent Application Publication
(10) Pub. No.: US 2020/0204715 A1
(43) Pub. Date: Jun. 25, 2020

(54) ELECTRONIC APPARATUS AND TERMINAL EQUIPMENT

(71) Applicant: INCOFLEX SEMICONDUCTOR TECHNOLOGY CO., LTD., Shaanxi (CN)

(72) Inventors: PAN OUYANG, SHAANXI (CN); YOUNG LI, SHAANXI (CN)

(21) Appl. No.: 16/726,654

(22) Filed: Dec. 24, 2019

(30) Foreign Application Priority Data
Dec. 25, 2018 (CN) 201822183868.6
Feb. 14, 2019 (CN) 201910113874.0

(51) Int. Cl. H04N 5/225; H01L 27/32

(52) U.S. Cl. CPC H04N 5/2257; H04M 1/0264; H01L 27/3211; H01L 27/3244

(57) ABSTRACT

An electronic apparatus is provided. The electronic apparatus includes a functional element and a display panel. The display panel includes a display area, a non-display area, a substrate, a thin-film transistor layer and an organic light emitting layer. The thin-film transistor layer is disposed above the substrate. The organic light emitting layer is disposed above the thin-film transistor layer. The functional element is disposed upon a side of the substrate away from the thin-film transistor layer.

### TECHNICAL FIELD

The present disclosure relates to display technology and, more particularly, to an electronic apparatus and a terminal equipment including a camera element.

### BACKGROUND

The full screen technology and full screen mobile terminals are some of the most popular technologies nowadays. The advancement in the display technology has allowed the user to have a stronger demand for a higher screen-to-body ratio. A broad definition of the full screen technology in the display industry refers to ultra-high screen-to-body ratio designs introduced in mobile phones. The full screen technology literally means that the front of a mobile phone can wholly serve as a display screen. Each of four borders of the mobile phone utilizes a bezel-less design in pursuit of an ultra-high screen-to-body ratio close to 100%. However, given the space limitations imposed by essential functional components of a mobile phone, such as a front-facing camera, an earpiece, a proximity sensor and a light sensor, it is necessary to provide a notch at the top of the display screen to house such functional components thereinto. In other words, a full screen mobile phone announced in the industry is merely a mobile phone with an ultra-high screen-to-body ratio, rather than a mobile phone with a screen-to-body ratio of 100%.

For example, a full screen mobile phone launched on the market refers to a mobile phone with a screen-to-body ratio of more than 90%, and features an ultra-narrow bezel design. Although some devices of a mobile, such as an earpiece, can have a reduced size to be hidden inside a bezel as a screen size tends to increase, a front-facing camera of the mobile phone can only be disposed under a display screen implemented using a hole-punch screen or a transparent screen. The hole-punch screen, such as a notch screen, a V-shaped notch screen or a waterdrop-shaped notch screen, will inevitably decrease a screen-to-body ratio and viewing experience. In other words, the hole-punch or notch design greatly hinders an increase in screen-to-body ratio, or causes a display screen to have an odd shape.

In other words, the related art ditches a notch in a display area to create a non-display area for installation of a front-facing camera. However, neither a ditched notch design nor a waterdrop-shaped notch design can prevent a display area loss, which seriously degrades design aesthetics and user experience. In addition, as pixel loss occurs in some areas on a body of the display screen, different areas on the body of the display screen will have a large load difference, which easily causes an area near the ditched notch to exhibit display imbalances and therefore affects a yield rate.

It should be noted that this section is intended to provide a background or context to the present disclosure that is recited in the claims. What is described in this section is not admitted to be prior art by inclusion in this section.

### SUMMARY

According to some embodiments of the present disclosure, an electronic apparatus is provided. The electronic apparatus includes a functional element and a display panel. The display panel includes a display area, a non-display area, a substrate, a thin-film transistor layer and an organic light emitting layer. The thin-film transistor layer is disposed above the substrate. The organic light emitting layer is disposed above the thin-film transistor layer. The functional element is disposed upon a side of the substrate away from the thin-film transistor layer.

According to some embodiments of the present disclosure, a terminal equipment is provided. The terminal equipment includes a functional element and a display panel. The display panel includes a display area, a non-display area, a substrate, a thin-film transistor layer and an organic light emitting layer. The thin-film transistor layer is disposed above the substrate. The organic light emitting layer is disposed above the thin-film transistor layer. The functional element is disposed upon a side of the substrate away from the thin-film transistor layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a top view of an exemplary electronic apparatus in accordance with some embodiments of the present disclosure.

FIG. 2 illustrates a side view of an exemplary electronic apparatus in accordance with some embodiments of the present disclosure.

FIG. 3 is a block diagram illustrating a full screen mobile phone in accordance with some embodiments of the present disclosure.

FIG. 4 is a cross-sectional view of a structure of the display screen shown in FIG. 1 in accordance with some embodiments of the present disclosure.

FIG. 5 is a diagram illustrating image formation in a camera mode of the full screen mobile phone shown in FIG. 3 in accordance with some embodiments of the present disclosure.

FIG. 6 illustrates a movement path of the front-facing camera shown in FIG. 5 in accordance with some embodiments of the present disclosure.

### EMBODIMENTS

Example implementations are now described more thoroughly with reference to the accompanying drawings. However, the example implementations can be implemented in a plurality of forms and should not be construed as being limited to the implementations described herein. On the contrary, these implementations are provided to make the present invention more comprehensive and complete, and fully convey the ideas of the example implementations to a person skilled in the art. The particular features, structures, materials, or characteristics may be combined in any suitable manner in one or more embodiments.

In addition, the drawings are only schematic illustration of the disclosure, and are not necessarily drawn to scale. The same reference numerals in the drawings denote the same or similar structures, and thus their detailed description will be omitted. Some of the block diagrams shown in the figures are functional entities and do not necessarily have to correspond to physically or logically separate entities.

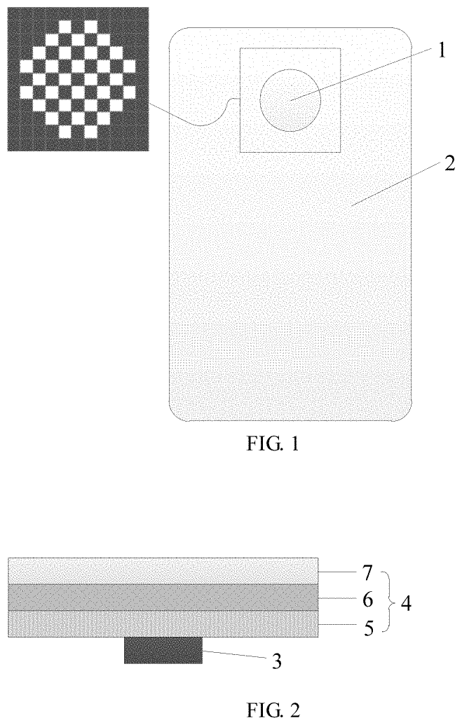

The present disclosure provides an electronic apparatus, which may include, but is not limited to, a terminal equipment such as a smartphone, a tablet computer, etc. As shown in FIG. 1 and FIG. 2, the electronic apparatus may include a functional element 3 and a display panel 4. Specifically, the display panel 4 may include a substrate 5, a thin-film transistor (TFT) layer 6 and an organic light emitting layer 7. The TFT layer 6 is disposed above the substrate 5, and the organic light emitting layer 7 is disposed above the TFT layer 6. The organic light emitting layer 7 includes a display area, including a first display area 1 and a second display area 2, wherein a pixel density of the first display area 1 is lower than a pixel density of the second display area 2, The functional element 3 is disposed upon a side of the substrate 5 away from the TFT layer 6, and is disposed in correspondence with the first display area 1.

The related art ditches a notch in a display area on a display panel to create a non-display area for installation of a front-facing camera. However, neither a ditched notch design nor a waterdrop-shaped notch design can prevent a display area loss, which seriously degrades design aesthetics and user experience. In addition, as pixel loss occurs in some areas on the display panel, different areas on the display panel will have a large load difference, which easily causes an area near the ditched notch to exhibit display imbalances and therefore affects a yield rate.

In some embodiments of the present disclosure, an organic light emitting layer of a display panel includes a first display area and a second display area disposed therein. A pixel density of the first display area is lower than a pixel density of the second display area. A functional element is disposed upon a bottom surface of the display panel, and is disposed in correspondence with the first display area. As a result, the present disclosure may not need to ditch a notch in a display area to create a non-display area for installation of a functional element, thus solving the problems of display imbalances exhibited by an area near a ditched notch. The display imbalances are easily caused by a large load difference between different areas on a body of a display screen, wherein the large load difference results from pixel loss in some areas on the body of the display screen. Furthermore, the present disclosure provides an under-display scheme which disposes a functional element under the display panel, thereby increasing a screen-to-body ratio of a display screen of the electronic apparatus. The proposed under-display scheme can achieve a true full screen display, and is easy to use.

Specifically, the electronic apparatus may further include a housing (not shown). The display panel 4 is installed on the housing. The functional element 3 is disposed inside the housing, and located on a side of the substrate 5 of the display panel 4 away from the TFT layer 6. Also, the functional element 3 is disposed in correspondence with the first display area 1. As those skilled in the art can understand that the housing may be implemented using various structures and materials, further description is omitted here for brevity.

The functional element 3 may at least include a camera element, a fingerprint recognition function key, an iris recognition function key, and one or more combinations thereof. The organic light emitting layer 7 may at least include an anode layer, an organic light emitting layer and a cathode layer stacked in sequence. In some embodiments, the organic light emitting layer 7 may further include one of more combinations of a hole injection layer, a hole transport layer, an electron transport layer and an electron injection layer. This is provided for illustrative purposes only, and is not intended to limit the scope of the present disclosure. As those skilled in the art can understand the fabrication processes of the organic light emitting layer 7 and the TFT layer 6, further description is omitted here for brevity.

In some embodiments, the first display area 1 and the second display area 2 are non-overlapping. When the first display area 1 overlaps with the second display area 2, a transmittance of the first display area 1 is affected, thus affecting performance and function of the functional element 3 disposed in correspondence with the first display area 1. For example, when the functional element 3 is implemented as a camera element, the transmittance of the first display area 1 decreases after the first display area 1 overlaps with the second display area 2. As a result, photos or videos taken by the camera element are obscured due to low transmittances. However, this is provided for illustrative purposes only, and is not intended to limit the scope of the present disclosure.

It is worth noting that, when a ratio of the pixel density of the first display area 1 to the pixel density of the second display area 2 is lower than ½, the pixel density of the first display area 1 may be too low, resulting in too poor display quality and degraded user experience. As a result, in some embodiments, a ratio of the pixel density of the first display area 1 to the pixel density of the second display area 2 may be greater than or equal to ½, such that the first display area 1 can display relatively high quality pictures while satisfying normal operating requirements of the functional element 3 such as a camera element.

In some embodiments, the first display area 1 is in a circle shape. In some embodiments, a shape of the first display area 1 can be adjusted according to requirement of the functional element 3. For example, in addition to a circle shape, the first display area 1 may be in other shapes such as a rectangle shape or a rhombus shape. Those skilled in the art can appreciate that this is not intended to limit the scope of the present disclosure.

In some embodiments, a diameter of the first display area 1 may be equal to or approximately equal to 3 micrometers (mm). It is worth noting that the first display area 1 has a lower pixel density. As a result, the smaller an area of the first display area 1 is, the higher the display quality can be. On the basis of such design concept, the first display area 1 can be implemented as a circular area having a diameter of 3 mm. Those skilled in the art can appreciate that this is not intended to limit the scope of the present disclosure.

In some embodiments, the electronic apparatus may further include a pixel driving circuit disposed in correspondence with each pixel. For example, the pixel driving circuit can be disposed above the TFT layer 6. Specifically, the pixel driving circuit may include one or more scan lines, one or more data lines, one or more capacitors, etc. Those skilled in the art can appreciate that this is not intended to limit the scope of the present disclosure.

In some embodiments, the pixel driving circuit may be a 7T2C pixel driving circuit or a 2T1C pixel driving circuit. The 7T2C pixel driving circuit includes seven transistors and two capacitors. The 2T1C pixel driving circuit includes two transistors and one capacitor. As those skilled in the art can understand the structure and operation associated with the 7T2C pixel driving circuit and the 2T1C pixel driving circuit, further description is omitted here for brevity. It is worth noting that the pixel driving circuit can be implemented by other types of pixel driving circuits without departing from the scope of the present disclosure.

In some embodiments, the functional element 3 can be a camera element. By way of example but not limitation, the functional element 3 may further include a fingerprint recognition function key, an iris recognition function key, and one or more combinations thereof. Those skilled in the art can appreciate that this is not intended to limit the scope of the present disclosure.

Moreover, in some embodiments, a size of the first display area 1 can be determined according to a size of the camera element, which can be disposed in correspondence with the first display area 1. As the size of the first display area 1 is expected to ensure normal operation of the camera element, it is appreciated that the size of the first display area 1 can be determined according to the size of the camera element. For example, the smaller the size of the camera element is, the smaller the size of the display area 1 is. As another example, the larger the size of the camera element is, the larger the size of the display area 1 is.

In some embodiments, the pixel density of the first display area 1 can be determined according to a transmittance required for the camera element, wherein the camera element is disposed in correspondence with the first display area 1. As the pixel density of the first display area 1 is expected to ensure normal operation of the camera element, it is appreciated that the pixel density of the first display area 1 can be determined according to the transmittance required for the camera element. For example, the higher the transmittance required for the camera element is, the lower the pixel density of the display area 1 is. As another example, the lower the transmittance required for the camera element is, the higher the pixel density of the display area 1 is.

In some embodiments of the present disclosure, an organic light emitting layer of a display panel includes a first display area and a second display area disposed therein. A pixel density of the first display area is lower than a pixel density of the second display area. A functional element is disposed upon a bottom surface of the display panel, and is disposed in correspondence with the first display area. As a result, the present disclosure may not need to ditch a notch in a display area to create a non-display area for installation of a functional element, thus solving the problems of display imbalances exhibited by an area near a ditched notch. The display imbalances are easily caused by a large load difference between different areas on a body of a display screen, wherein the large load difference results from pixel loss in some areas on the body of the display screen. Furthermore, the present disclosure provides an under-display scheme which disposes a functional element under the display panel, thereby increasing a screen-to-body ratio of a display screen of the electronic apparatus. The proposed under-display scheme can achieve a true full screen display, and is easy to use.

In some embodiments, when a display panel has a low or moderate transmittance, e.g. 40% to 70%, a camera element such as a front-facing camera may produce a blurry image. One approach for further increasing screen-to-body ratios is to increase a transmittance of the display panel. This approach focuses on reducing an area occupied by a pixel (e.g. referred to as a pixel area) or reducing the number of pixels. However, reducing a pixel area makes it more difficult to fabricate the display panel. In addition, compared to a large pixel area lit up by the display panel having a predetermined brightness level, the display panel has to provide light having relatively high intensity to light up a small pixel area, thus shorting the service life of the display panel. Moreover, when the number of pixels in a display area decreases, pixels per inch (PEI, also referred to as a pixel density) in this display area will decrease accordingly, causing grainy images to be presented on the display panel.

To solve the aforementioned issue, the present disclosure may further provide an electronic apparatus or a terminal equipment, such as a full screen mobile phone, which includes a camera element disposed under a display panel. When the electronic apparatus operates in a mode where the camera element is turned on, a control module of the electronic apparatus can be configured to turn off pixels on and around the camera element such that the pixels are unlighted. As a result, a clear or high-resolution image can be obtained by the camera element disposed under the display panel.

Additionally, the present disclosure may further utilize fine metal mask (FMM) evaporation to form an organic light emitting layer of the display panel such as an OLED display screen. The FMM evaporation can allow an area where no pixel is disposed (e.g. referred to as a non-pixel area) to be freed from material deposition, thus increasing a transmittance of this non-pixel area.

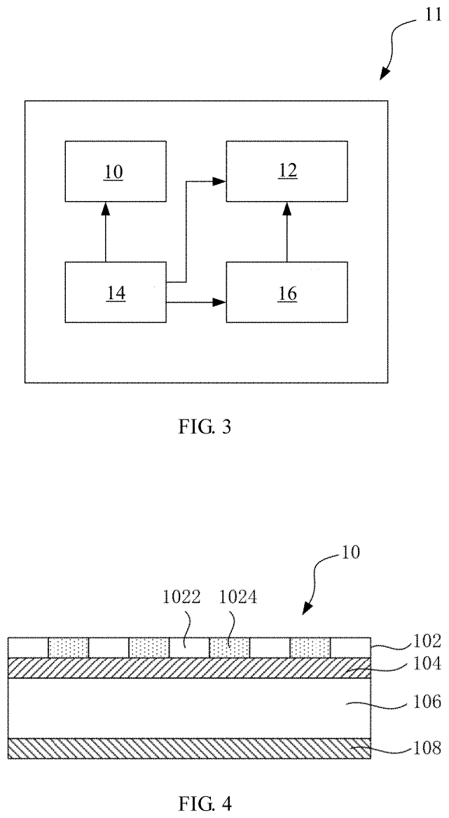

FIG. 3 is a block diagram illustrating the electronic apparatus shown in FIG. 1 in accordance with some embodiments of the present disclosure. In the present embodiment, the electronic apparatus 11 can be implemented as a full screen mobile phone. As shown in FIG. 3, the electronic apparatus 11 at least includes a display panel 10, a camera element 12 and a control module 14. The control module 14 is electrically connected to the display panel 10 and the camera element 12.

The display panel 10 can be an embodiment of the display panel 4 shown in FIG. 2. The camera element 12 can be an embodiment of the functional element 3 shown in FIG. 2. By way of example but not limitation, a display area of the display panel 10 may include a first display area and a second display area, wherein the first display area may have a lower pixel density than the second display area. The camera element 12 can be disposed under the display panel 10, e.g. disposed under the first display area of the display panel 10. The camera element 12 can be implemented as a front-facing camera.

In the present embodiment, the display panel 10 may at least include a transparent substrate 102, an anode 104, an organic electroluminescent diode layer 106 and a cathode 108 disposed one over another as illustrated in FIG. 4. The transparent substrate 102 can be an embodiment of the substrate 5 shown in FIG. 2. The organic electroluminescent diode layer 106 can be an embodiment of at least a portion of the organic light emitting layer 7 shown in FIG. 2. For example, the organic light emitting layer 7 shown in FIG. 2 can be implemented to include the anode 104, the organic electroluminescent diode layer 106 and the cathode 108.

The camera element 12 may be disposed upon a side of the transparent substrate 102 away from the organic electroluminescent diode layer 106. In addition, the transparent substrate 102 includes a pixel area 1022 and a non-pixel area 1024 formed thereon. By way of example but not limitation, a first display area of the display panel 10 where the camera element 12 is disposed may include the pixel area 1022 and the non-pixel area 1024.

In the present embodiment, the organic electroluminescent diode layer 106 may be formed using fine metal mask (FMM) evaporation. A mask used in the FMM evaporation can be a non-metal mask or a metal mask. The FMM evaporation is utilized to allow the non-pixel area 1024 to be freed from material deposition. For example, an empty space may be left between two consecutive pixel areas. As a result, the proposed display screen can overcome the problems encountered in utilizing a common metal mask (CMM) to form an organic electroluminescent diode layer. For example, when the organic electroluminescent diode layer 106 is formed using a CMM, materials will be deposited in the non-pixel area 1024, thus decreasing a transmittance of the non-pixel area 1024.

In addition, for the sake of clarity and simplicity, the present disclosure will mainly focus on imaging features of the electronic apparatus 11 which has the camera element 12 disposed under the display panel 10. Functions of other components of the electronic apparatus 11, as well as connection between the components, can be similar/identical to those provided in the existing art. Further, as such components are not the focus of the present disclosure, associated description will not be provided herein.

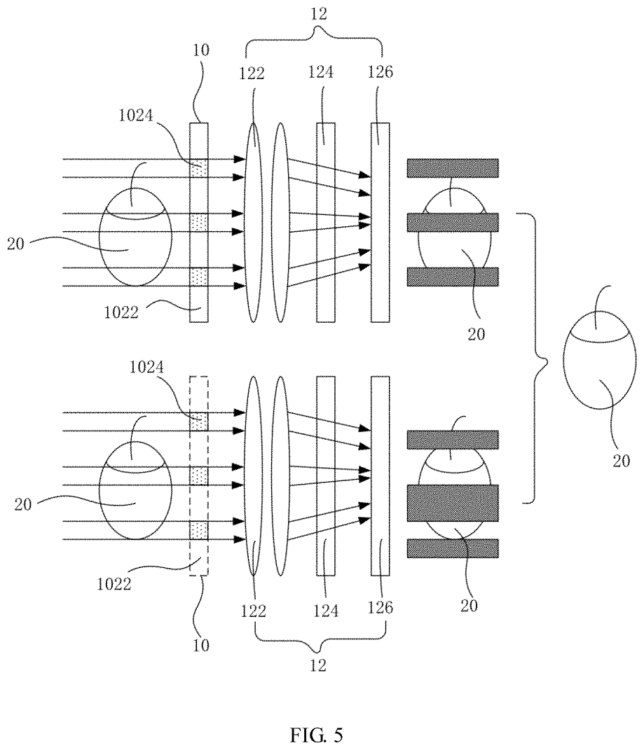

FIG. 5 is a diagram illustrating image formation in a camera mode of the electronic apparatus 11 shown in FIG. 3 in accordance with some embodiments of the present disclosure. Referring to FIG. 5 and also to FIG. 3, in the present embodiment, the control module 14 can controls pixel around the camera element 12 to be unlighted.

At the upper portion of FIG. 5, the camera element 12 is configured to shoot an object 20 in front of the display panel 10. The produced optical image is processed by the color filter array 124 and the image array 126, and then projected onto a sensor (not shown in FIG. 5). Next, the optical image is converted into an electronic signal, and the electronic signal is converted into a digital signal through analog-to-digital conversion. The digital signal is processed by a digital signal processor (DSP), and sent to a processor (not shown in FIG. 5) of the electronic apparatus 11 for further processing. In the situation described above, as the optical image of the object 20 pass through the pixel area 1022 and the non-pixel area 1024 on the display panel 10 concurrently, some portions of the optical image are blocked such that the resulting image of the object 20 outputted from the camera element 12 will be blurred.

At the bottom portion of FIG. 5, when the electronic apparatus 11 operates in a mode where the camera element 12 is turned on, the display panel 10 can have an increased transmittance since materials are deposited in the pixel area 1022 while the non-pixel area 1024 is freed from material deposition. As a result, when the electronic apparatus 11 operates in a mode where the camera element 12 is turned on, the control module 14 in the electronic apparatus 11 can control pixels surrounding the camera element 12, e.g. pixels located on a top side, a bottom side, a left side and a right side of the camera element 12, to be unlighted. In other words, the control module 14 can turn off the pixels surrounding the camera element 12. Additionally, the control module 14 can transmit a signal to a moving mechanism 16, which is electrically connected to the control module 14 and the camera element 12, and enable the moving mechanism 16 to drive the camera element 12 to start moving. A movement path of the camera element 12 controlled by the moving mechanism 16 may be linear, curvilinear, polygonal, circular, oval, or irregular in shape. Further, when moving according to the movement path, the camera element 12 can bypass the unlighted pixels, thus preventing a portion of an image, captured using the camera element 12, from being blocked by such unlighted pixels. In other words, the control module 14 can control the movement path of the camera element 12 to bypass the pixels according to arrangement of the pixels on the transparent substrate 102 such that an image inputted to the camera element 12 is unshielded from the pixels

For example, when the camera element 12 is unmoved, a portion of the object 20 in front of the display panel 10 is shielded from the camera element 12 by the pixels in front of the front-facing camera 12. When the control module 14 is configured to control the camera element 12 to move in the movement path to bypass the pixels, the camera element 12 is configured to receive image information of the portion of the object 20 shielded by the pixels. As a result, the camera element 12 can obtain a high-resolution image.

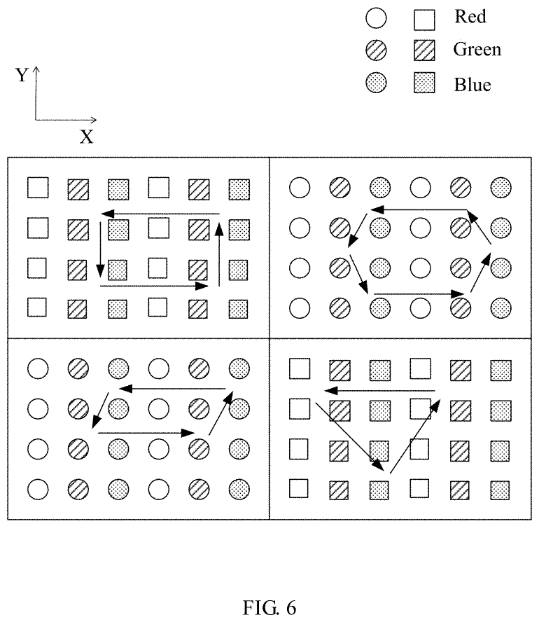

Some embodiments of the movement path and associated movement control described above are given in the following to facilitate an understanding of the present disclosure. FIG. 6 illustrates a movement path of the camera element 12 shown in FIG. 5 in accordance with some embodiments of the present disclosure. Referring to FIG. 6, as described above, when the electronic apparatus 11 operates in a mode where the camera element 12 is turned on, the control module 14 can send a signal to the moving mechanism 16 such that the moving mechanism 16 can start to drive the camera element 12 to move. In the present embodiment, the moving mechanism 16 can be implemented to include, or implemented as, a micro dual-shaft moving mechanism including an X movement axis and a Y movement axis. The X movement axis may include an X1 movement subaxis and an X2 movement subaxis. The Y movement axis may include a Y1 movement subaxis and a Y2 movement subaxis. The X1 movement subaxis and the Y1 movement subaxis can be used to define a fine movement, while the X2 movement subaxis and the Y2 movement subaxis can be used to define a coarse movement. The fine movement, defined by the X1 and Y1 movement subaxes, refers to a movement of the camera element 12 having a small amplitude and low speed. The fine movement can allow the camera element 12 to obtain more image information associated with the object 20, thus producing a clearer image. The coarse movement, defined by the X2 and Y2 movement subaxes, refers to a movement of the camera element 12 having a large amplitude and high speed. Compared to the fine movement, the coarse movement would cause the camera element 12 to obtain less image information associated with the object 20. The resulting image of the object 20 may be unclear.

In some embodiments, in order to obtain high-resolution images, the control module 14 may control the X1 movement subaxis and the Y1 movement subaxis of the micro dual-shaft moving mechanism 16 to drive the camera element 12 to move in a movement path such as a square or rectangular moving path shown at the top-left portion of FIG. 6, a polygonal moving path shown at the top-right portion of FIG. 6, a quadrilateral moving path shown at the bottom-left portion of FIG. 6, or a triangular moving path shown at the bottom-right portion of FIG. 6. In addition, the movement path of the camera element 12 may bypass pixels which are turned off, such as one or more unlighted red pixels, one or more unlighted green pixels, or one or more unlighted blue pixels. As a result, the micro dual-shaft moving mechanism 16 can prevent a portion of an image, captured using the camera element 12, from being blocked by the turned off pixels. The camera element 12 can obtain a high-resolution image.

In the description, it is to be understood that terms such as “central”, “longitudinal”, “transverse”, “length” “width”, “thickness”, “upper”, “lower,” “front”, “rear”, “left”, “right”, “vertical”, “horizontal”, “top”, “bottom”, “inner”, “outer”, “clockwise” and “counterclockwise” should be construed to refer to the orientation as then described or as shown in the drawings under discussion. These relative terms are for convenience of description, and do not indicate or imply that the present disclosure have a particular orientation or be constructed or operated in a particular orientation, thus cannot be construed to limit the present disclosure.

In addition, terms such as “first” and “second” are used herein for purposes of description and are not intended to indicate or imply relative importance or significance or to imply the number of indicated technical features. Thus, the feature defined with “first” and “second” may include one or more of this feature. In the description of the present disclosure, “a plurality of” means two or more than two, unless specified otherwise.

In the present disclosure; unless specified or limited otherwise, the terms “mounted,” “connected,” “coupled,” “fixed” and the like are used broadly, and may be, for example, fixed connections, detachable connections, or integral connections; may also be mechanical or electrical connections; may also be direct connections or indirect connections via intervening structures; may also be inner communications of two elements, which can be understood by those skilled in the art according to specific situations.

In the present disclosure, unless specified or limited otherwise, a structure in which a first feature is “on” or “below” a second feature may include an embodiment in which the first feature is in direct contact with the second feature, and may also include an embodiment in which the first feature and the second feature are not in direct contact with each other, but are contacted via an additional feature formed therebetween. Furthermore, a first feature “on”, “above”, or “on top of” a second feature may include an embodiment in which the first feature is right or obliquely “on”, “above”, or “on top of” the second feature, or just means that the first feature is at a height higher than that of the second feature.

Reference throughout this specification to “an embodiment,” “some embodiments,” “an example,” “a specific example,” or “some examples,” means that a particular feature, structure, material, or characteristic described in connection with the embodiment or example is included in at least one embodiment or example of the present disclosure. Thus, the appearances of the phrases in various places throughout this specification are not necessarily referring to the same embodiment or example of the present disclosure. Furthermore, the particular features, structures, materials, or characteristics may be combined in any suitable manner in one or more embodiments or examples. In addition, those skilled in the art may combine and combine the different embodiments or examples described in this specification and features of different embodiments or examples without conflicting with each other.

Although embodiments have been shown and described, it would be appreciated that the above embodiments are explanatory and cannot be construed to limit the present disclosure, and changes, modifications, alternatives and variants can be made in the embodiments by those skilled in the art in the scope of the present disclosure.

Other embodiments of the present disclosure will be apparent to those skilled in the art from consideration of the specification and practice of the present disclosure disclosed here. This application is intended to cover any variations, uses, or adaptations of the present disclosure following the general principles thereof and including such departures from the present disclosure as come within known or customary practice in the art. It is intended that the specification and examples be considered as exemplary only, with a true scope and spirit of the present disclosure being indicated by the following claims.

What is claimed is:

1. An electronic apparatus, comprising:
a functional element; and
a display panel comprising a display area, a non-display area, and
a substrate;
a thin-film transistor layer, disposed above the substrate; and
an organic light emitting layer, disposed above the thin-film transistor layer;
wherein the functional element is disposed upon a side of the substrate away from the thin-film transistor layer.

2. The electronic apparatus of claim 1, wherein the functional element is a camera element.

3. The electronic apparatus of claim 2, wherein the display area comprises a first display area and a second display area, and a pixel density of the first display area is lower than a pixel density of the second display area.

4. The electronic apparatus of claim 2, wherein the first display area and the second display area are non-overlapping.

5. The electronic apparatus of claim 3, wherein the camera element is disposed in correspondence with the first display area.

6. The electronic apparatus of claim 3, wherein a ratio of the pixel density of the first display area to the pixel density of the second display area is greater than or equal to ½.

7. The electronic apparatus of claim 3, wherein the first display area is in a circle shape.

8. The electronic apparatus of claim 7, wherein a diameter of the first display area is approximately 3 micrometers.

9. The electronic apparatus claim 3, further comprising a pixel driving circuit disposed in correspondence with each pixel and disposed above the thin-film transistor layer.

10. The electronic apparatus of claim 9, wherein the pixel driving circuit comprises a 7T2C pixel driving circuit or a 2T1C pixel driving circuit.

11. The electronic apparatus of claim 3, wherein a size of the first display area is determined according to a size of the camera element.

12. The electronic apparatus of claim 11, wherein the pixel density of the first display area is determined according to a transmittance required for the camera element.

13. The electronic apparatus of claim 2, further comprising a control module electrically connected to the display panel and the camera element, wherein when the electronic apparatus operates in a mode where the camera element is turned on, the control module is configured to turn off pixels around the camera element such that the pixels are unlighted, and the control module is configured to control a movement path of the camera element to bypass the pixels according to arrangement of the pixels on the substrate such that an image inputted to the camera element is unshielded from the pixels.

14. The electronic apparatus of claim 13, wherein when the camera element is unmoved, a portion of an object in front of the display panel is shielded from the camera element by the pixels in front of the camera element; when the control module is configured to control the camera element to move in the movement path to bypass the pixels, the camera element is configured to receive image information of the portion of the object shielded by the pixels.

15. The electronic apparatus of claim 13, wherein the movement path of the camera element is linear, curvilinear, polygonal, circular, oval, or irregular in shape.

16. The electronic apparatus of claim 13, further comprising:
a moving mechanism, coupled to the camera element, configured to move the camera element.

17. The electronic apparatus of claim 16, wherein the moving mechanism comprises micro dual-shaft moving mechanism.

18. The electronic apparatus of claim 1, wherein the organic light emitting layer further comprises an anode and a cathode.

19. A terminal equipment, comprising:
a functional element; and
a display panel comprising a display area, a non-display area, and
a substrate;
a thin-film transistor layer, disposed on the substrate; and
an organic light emitting layer, disposed above the thin-film transistor layer;
wherein the functional element is disposed upon a side of the substrate away from the thin-film transistor layer.
